(19) United States
(12) Patent Application Publication
(10) Pub. No.: US 2018/0076758 A1
(43) Pub. Date: Mar. 15, 2018

(54) Three-Dimensional Elongated Photovoltaic Cell Assemblies

(71) Applicant: Jesus Miranda, Miami, FL (US)

(72) Inventor: Jesus Miranda, Miami, FL (US)

(21) Appl. No.: 15/263,094

(22) Filed: Sep. 12, 2016

(51) Int. Cl. H02S 30/10; H01L 31/043; H01L 31/049; H01L 31/14; H01L 31/0203; H02S 40/22; H02S 40/34; H02S 40/32; H02S 40/38

(52) U.S. Cl. CPC H02S 30/10; H01L 31/043; H01L 31/049; H01L 31/143; H02S 40/38; H02S 40/22; H02S 40/34; H02S 40/32; H01L 31/0203

(57) ABSTRACT

Three-dimensional photovoltaic assemblies capable of greater electric power output and more consistent power profiles than flat photovoltaic systems of the prior art with the same footprint are disclosed. The assemblies are comprised of a plurality of elongated photovoltaic modules arranged to project radially outward from a central trunk. In some embodiments, elongated photovoltaic modules comprise an elongated prismatic body having a multi-sided polygonal cross-section, wherein the lateral sides of the elongated body define non-parallel rectangular panels and photovoltaic cells are mounted on at least two of the lateral sides or panels of the elongated body. The photovoltaic cells on the plurality of elongated photovoltaic modules can be exposed to the radiant energy of the sun at a plurality of angles of incidence at any given point in time of day.

### TECHNICAL FIELD

The present invention relates to photovoltaic cell assemblies and more particularly to three-dimensional elongated photovoltaic cell assemblies.

### BACKGROUND

Photovoltaic cells, also known as solar cells are increasingly being utilized as a source of clean renewable energy. Photovoltaic cells can convert radiant sunlight energy into direct current electrical energy.

Photovoltaic cells comprise layers of conducting and semi-conducting materials and are typically constructed as wafers having flat structures that can be connected together to form flat photovoltaic modules or panels. Modules can in turn be connected to form photovoltaic arrays or assemblies. Photovoltaic modules of the prior art are commonly mounted on flat supporting structures providing flat assemblies with overall two-dimensional configurations. Elongated photovoltaic cells are also known and can comprise cylindrical conductor and photovoltaic layers encasing an elongated core electrode. Elongated photovoltaic cells of the prior art are usually assembled in parallel arrangements as two-dimensional structures.

The surface of photovoltaic cells must face the direction of the sun in order to absorb sunlight and produce the desired electricity. Electric output from a photovoltaic cell is greatest when the cell faces directly towards the sun, that is, the sun is at a 90 degree angle to the cell surface (0 degree angle of incidence), and output decreases as the cell faces further away from the sun (increasing angle of incidence). Thus, flat photovoltaic cell assemblies installed in a fixed position can suffer from significant daily electric output variability. Daily electric output variability can be a significant issue facing the incorporation of photovoltaic assemblies into existing electric grids. To minimize daily output variability, flat photovoltaic assemblies can be placed on motorized platforms (trackers) that track the movement of the sun throughout the day. Trackers, however, can be expensive to install and maintain.

Thus, there is a need to reduce daily solar electric output variability in order to facilitate integration of photovoltaic assemblies into the electric grid. Efficient and cost effective means of reducing variability caused by daily movement of the sun are needed that do not involve the use of trackers.

Furthermore, since the amount of electricity generated by photovoltaic assemblies is directly related to the total photovoltaic cell surface area or footprint covered by flat photovoltaic assemblies, large assembly footprints are required when attempting to produce large quantities of electricity. Thus, there is also a need for increased photovoltaic electric power output from a given assembly footprint.

### SUMMARY

An object of the present invention is to provide three-dimensional elongated photovoltaic cell assemblies with reduced daily solar electric power output variability than flat two-dimensional assemblies of the prior art. Three-dimensional elongated photovoltaic cell assemblies of the present invention are comprised of a plurality of elongated photovoltaic modules configured to project radially outward from a central trunk in a plurality of spatial directions. In some embodiments, an elongated photovoltaic module comprises an elongated body such as a multi-sided prism having a module basal end, a module distal end and a polygonal cross-section parallel to the module basal end, wherein the lateral sides of the elongated body define non-parallel elongated rectangular panels. Each elongated photovoltaic module further comprises a module electric circuit with means of conducting electricity between the module basal end and the module distal end. Photovoltaic cells are mounted on at least two of the lateral sides or panels of the elongated body and electrically connected to the module electric circuit. The elongated body can be solid, hollow or tubular. The basal end of each elongated photovoltaic module is physically attached to the lateral surface of the central trunk while the distal end is oriented to project radially outward from the central trunk. The central trunk comprises a trunk body having a first trunk end, a second trunk end and a trunk lateral surface. The central trunk functions as a central attachment hub for the elongated photovoltaic modules and is provided with a central electric circuit with means of conducting electricity between the first trunk end and the second trunk end. A means of connecting the module electric circuit of the plurality of elongated photovoltaic modules to the trunk central electric circuit is provided and a means of connecting the trunk central electric circuit to an external circuit is also provided. The exact shape of the central trunk body is not critical to the present invention and can be for example cylindrical, pyramidal, conical, spherical or prismatic. Possible shapes for the central trunk include cylinders, pyramids, pyramidal frustums, spheres, spherical frustums, cones, and conical frustums. A cross-section parallel to the base of the central trunk can describe a circle, semi-circle, oval, oblong, parabola, curvilinear polygon, ellipse, polygon or an irregular shape.

The plurality of elongated photovoltaic modules project radially from the central trunk in a plurality of spatial directions and can be uniformly distributed about the central trunk with adjacent modules pointing in different spatial directions. It is desirable to distribute elongated photovoltaic modules on the central trunk such that modules provide minimal shading to adjacent modules. The elongated photovoltaic modules can be attached from completely around the perimeter or circumference of the central trunk to as little as half the perimeter or circumference of the central trunk. The exact shape of the elongated body of elongated photovoltaic modules is not a critical parameter of the present invention and can be for example cylindrical, pyramidal, conical or prismatic to name a few. The three-dimensional arrangement of the elongated photovoltaic modules, in conjunction with photovoltaic cells being provided on several lateral sides of the elongated modules, can present an assembly's photovoltaic cells to the sun at a plurality of angles of incidence at any given time of the day. The average angles of incidence of photovoltaic assemblies of the present invention exhibit less intraday variability than the angles of incidence of flat assemblies of the prior art. Reduced angle of incidence variability can result in more consistent sunlight absorption and in turn more uniform electricity production throughout the day. A more uniform amount of light can be absorbed by the three-dimensional elongated photovoltaic cell assemblies of the present invention and thus alleviate the deficiency of prior art flat photovoltaic cell assemblies of having to track the sun.

Another object of the present invention is to provide three-dimensional elongated photovoltaic cell assemblies with greater power output than flat photovoltaic assemblies with the same footprint. Since the length or height of the central trunk can be increased without impacting the assembly footprint, the number of elongated photovoltaic modules and thus photovoltaic cell area of a three-dimensional elongated photovoltaic cell assembly of the present invention can be increased over what is possible for a flat assembly having an equivalent footprint. Increased photovoltaic cell area can result in increased overall power output from three-dimensional elongated photovoltaic cell assemblies of the present invention over what is possible from flat assemblies of the prior art with the same footprint.

In some embodiments of the present invention, an elongated photovoltaic module comprises photovoltaic cells electrically connected in series and/or parallel mounted on the surface of an elongated body. The elongated body can be a multi-sided prism, pyramid or pyramidal frustum with a cross-section of the elongated body being described by a polygon such as a triangle, square, diamond, rectangle, trapezoid, pentagon, hexagon, or octagon to name a few. Flat photovoltaic cells are mounted along the length of at least two of the lateral sides of the elongated body. The lateral sides of the multi-sided elongated body function essentially as non-parallel elongated panels that allow for photovoltaic cells to face in several directions; this is in contrast to flat assemblies of the prior art where all of the cells face in the same direction.

In some embodiments, the elongated body of a photovoltaic module can be cylindrical or conical with a cross-section parallel to the base of the elongated body being described by a circle, semi-circle, oval, oblong, ellipse, curvilinear shape such as a parabola, or an irregular curved shape, and curved photovoltaic cells are mounted along the length of the elongated body. Cylindrical and conical elongated photovoltaic modules can have photovoltaic cells covering from about 90 degrees to 360 degrees around the central axis of the modules allowing for the photovoltaic cells to face in a multitude of directions.

In some embodiments, a cross-section of the elongated body can describe a curvilinear polygon consisting of circular arcs and photovoltaic cells are mounted along the length of at least two of the circular arc lateral sides. With circular elongated photovoltaic modules, as with multi-sided modules, photovoltaic cells face in several directions at the same time. When elongated photovoltaic modules are not provided on all lateral sides of the elongated body, modules are oriented on the central trunk such that the lateral sides of the modules with photovoltaic cells can face up. Additionally the central trunk tilt angle can be adjusted depending on the assembly installation location, time of year, or even time of day.

Elongated photovoltaic modules can be constructed out of rigid or flexible materials, can be designed to be straight or curved, and can comprise transparent materials in order to maximize light transmission through the assemblies. Furthermore, individual elongated photovoltaic modules can be protected from the environment by a transparent weather-proof protective covering with a material being selected for optimized absorption of sunlight energy. A three-dimensional elongated photovoltaic assembly of the present invention can have elongated photovoltaic modules all of the same type, size, length or shape, or alternatively the modules can be of various types, sizes, lengths or shapes. The photovoltaic cells utilized in the present invention can be selected from any of the different types of available photovoltaic cells, including, but not limited to amorphous silicon, crystalline silicon, thin film, nanocrystal, cadmium telluride, carbon nanotube, and gallium arsenide germanium. Double-sided photovoltaic cells, as well as multi p-n junction photovoltaic cells can also be utilized.

In some embodiments of the present invention, elongated photovoltaic modules can comprise an elongated conductive inner core electrode encased by layers of photovoltaic materials and a transparent conductive outer electrode. Elongated photovoltaic modules having inner core electrodes can have a circular cross-section resulting in cylinder-shaped bodies. Other cross-section shapes are possible such as triangles, squares, and semi-circles to name a few.

Elongated photovoltaic modules can also be constructed using any of the methods taught in the art for constructing elongated solar cells. For example, U.S. Pat. No. 7,196,262 and No. 8,742,252 describe elongated solar cells that can be used as elongated photovoltaic modules in the present invention. U.S. Pat. No. 8,067,688 to Gronet et al. discloses a solar cell assembly comprised of elongated solar cells. The elongated solar cells of the '688 patent are arranged parallel to each other in a planar array and not in the three-dimensional arrangement of the present invention.

In other embodiments of the present invention, elongated photovoltaic modules can comprise an elongated body covered by a thin flexible photovoltaic sheet. Thin flexible photovoltaic sheets can first be produced in roll form and subsequently cut to the desired size and then secured around an elongated body to produce an elongated photovoltaic module.

In some embodiments, elongated photovoltaic modules are provided with an electrical/structural support module base at their basal end, and the central trunk is provided with a plurality of socket connectors. Module bases can provide both a means of physically securing the elongated photovoltaic modules to the central trunk and a means of electrically connecting the elongated photovoltaic modules to the central electric circuit via the socket connectors. The central electric circuit can comprise a network of other elongated photovoltaic modules connected in series, in parallel, or a combination of series and parallel to provide the desired electric output. Bypass diodes can be included in the circuit to account for any photovoltaic cells not exposed to sunlight (shaded) at any given time throughout the day. Other components and capabilities such as, but not limited to, chargers, inverters, maximum power point tracking, blocking diodes, and batteries can be included with the three-dimensional elongated photovoltaic cell assemblies of the present invention in the construction of photovoltaic energy systems.

In some embodiments of the present invention, elongated photovoltaic modules function as luminescent elongated solar concentrators and comprise a luminescent elongated body with at least one photovoltaic cell provided on at least one end of the luminescent elongated body. Sunlight absorbed by the luminescent elongated body can be converted to fluorescence and guided to the photovoltaic cell(s) to produce electricity.

Visual indicators such as light emitting diodes (LEDs) can be integrated into the assemblies of the present invention as a means for indicating the functioning state of the elongated photovoltaic modules. Visual indicators can be useful for identifying a defective elongated photovoltaic module not producing electricity in the specified range that needed to be replaced or repaired. Alternatively, visual indicators can indicate when the elongated photovoltaic modules were producing electricity within their specified limits.

Photovoltaic assemblies of the present invention can also be installed within protective enclosures. An enclosure can comprise a container of transparent material with a reflective interior surface. Reflective surfaces can also be placed in the proximity of the assemblies as means of increasing the amount of solar irradiance reaching the assemblies.

Additionally, three-dimensional elongated photovoltaic cell assemblies of the present invention can be designed to be more visually appealing than the traditional flat designs of the prior art. For example, the assemblies can be designed to resemble trees and as such can be less obtrusive and easier to architecturally integrate than flat assemblies.

### BRIEF DESCRIPTION OF THE DRAWINGS

FIG. 1 illustrates a perspective view of a three-dimensional elongated photovoltaic cell assembly according to the present invention.

FIG. 2 illustrates a perspective view of a three-dimensional elongated photovoltaic cell assembly according to the present invention and represents a detailed view of the photovoltaic assembly of FIG. 1.

FIG. 3 illustrates a top view of the three-dimensional elongated photovoltaic cell assembly of FIG. 2.

FIG. 4A illustrates a perspective view of an elongated photovoltaic module having a multi-sided elongated body (trapezoidal prism) with photovoltaic cells provided on the top three lateral sides as used in conjunction with the three-dimensional elongated photovoltaic cell assembly of FIG. 3.

FIG. 4B is a cross-sectional detail view showing the distal end of the elongated photovoltaic module of FIG. 4A.

FIG. 5 illustrates some of the electrical connections of a three-dimensional elongated photovoltaic cell assembly according to another embodiment of the present invention.

FIG. 6 shows solar radiation intensity as a function of solar angle received by the photovoltaic cells of the three-dimensional elongated photovoltaic cell assembly of FIG. 1 compared to a flat assembly.

FIGS. 7A and 7B illustrate perspective views of two vertical cylindrically shaped three-dimensional elongated photovoltaic cell assemblies having different quantities of elongated photovoltaic modules according to the present invention.

FIG. 8 shows a plot of the solar irradiance profiles for the three-dimensional elongated photovoltaic cell assemblies of FIGS. 7A and 7B compared to a flat photovoltaic assembly.

FIGS. 9A, 9B, 10A, 10B, 11A, 11B, 12A, and 12B illustrate various embodiments of elongated photovoltaic modules having elongated bodies of different shapes that can be utilized with the present invention.

FIG. 13 shows the solar irradiance profiles for three-dimensional elongated photovoltaic cell assemblies of the present invention comprised of the elongated photovoltaic modules of FIGS. 9A, 10A, 11A, and 12A compared to a flat photovoltaic assembly.

FIG. 14 illustrates a perspective view of elongated photovoltaic modules having means of coupling together to form a longer elongated photovoltaic module with increased photovoltaic capacity that can be utilized with the present invention.

FIG. 15 illustrates a perspective view of a three-dimensional elongated photovoltaic cell assembly according to the present invention having a pine tree shape comprised of a plurality of interconnected three-dimensional elongated photovoltaic cell assemblies according to the present invention.

FIG. 16 illustrates a perspective view of a three-dimensional elongated photovoltaic cell assembly according to the present invention having elongated photovoltaic modules configured at various attachment angles relative to the central trunk.

FIG. 17 illustrates a perspective view of a three-dimensional elongated photovoltaic cell assembly according to the present invention positioned within a protective enclosure and also provided with adjacent reflective surfaces.

### DETAILED DESCRIPTION OF THE INVENTION

By referencing preferred embodiments the present invention is described in greater detail in the detailed description and illustrated in the appended drawings. The drawings are not necessarily to scale and are intended to better illustrate different aspects of the embodiments of the invention. The specific details and embodiments are provided for illustrative purposes and are not intended to limit the scope of the invention.

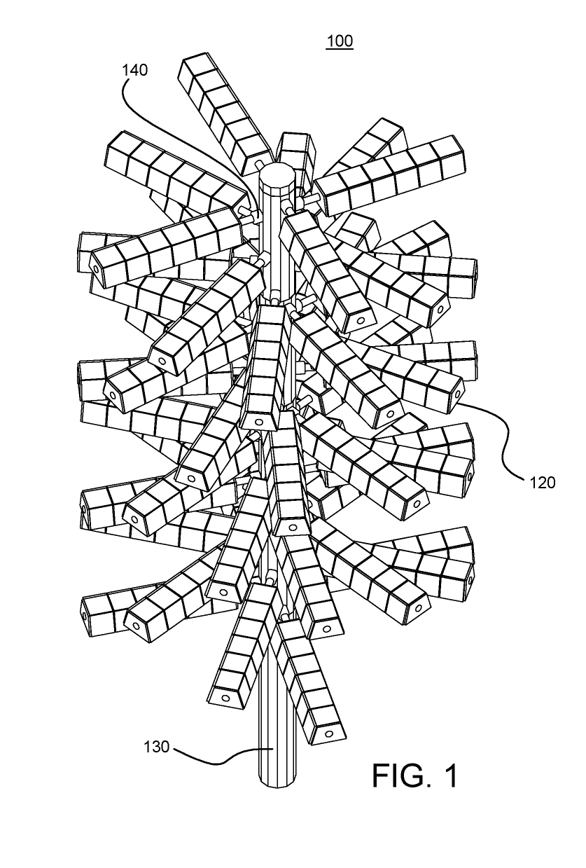

FIG. 1 is a perspective view of three-dimensional elongated photovoltaic cell assembly 100 according to one embodiment of the present invention. For the purpose of clarity, the embodiment illustrated in FIG. 1 is a simplified example of the present invention. Three-dimensional elongated photovoltaic cell assembly 100 comprises, but is not limited to, a central trunk 130, comprising a prismatic 12-sided shaft; a plurality of socket connectors 140 distributed on the lateral surface of the central trunk 130; and a plurality of elongated photovoltaic modules 120, each elongated photovoltaic module 120 being attached by their basal end to the central trunk 130 via a socket connector 140.

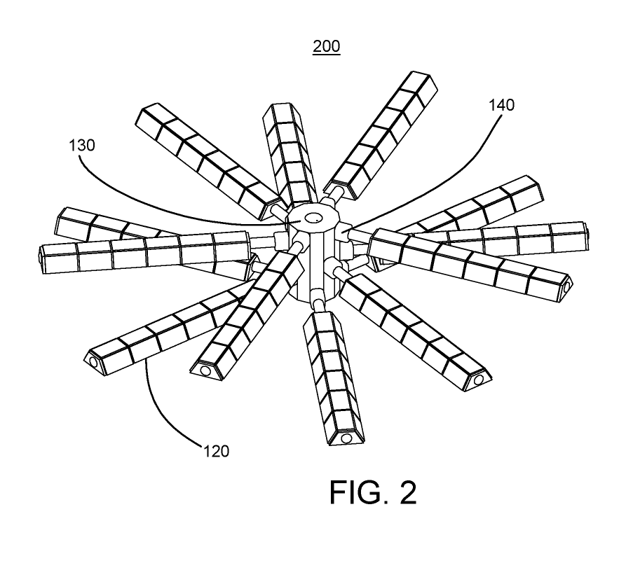

FIG. 2 shows a perspective view of three-dimensional elongated photovoltaic cell assembly 200, illustrating a further simplified embodiment of a three-dimensional elongated photovoltaic cell assembly of the present invention. Three-dimensional elongated photovoltaic cell assembly 200 represents a sub-assembly of three-dimensional elongated photovoltaic cell assembly 100 of FIG. 1; with three-dimensional elongated photovoltaic cell assembly 100 being comprised of four three-dimensional elongated photovoltaic cell assemblies 200. Socket connectors 140 and thereby elongated photovoltaic modules 120 are attached to the central trunk 130 and distributed around the central trunk 130.

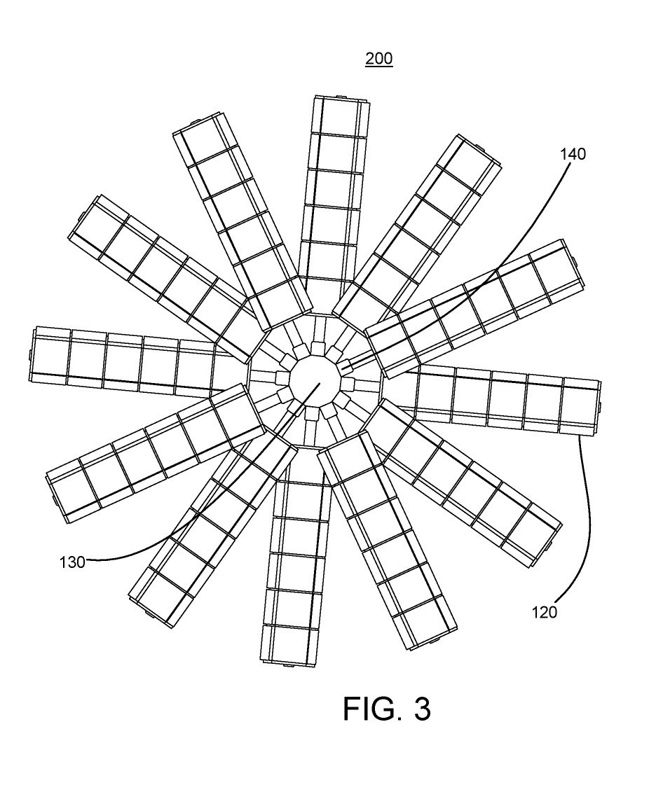

FIG. 3 is a top view of three-dimensional elongated photovoltaic cell assembly 200 of FIG. 2 and shows how a socket connector 140 is attached to each of the 12 lateral sides of central trunk 130 and thus the elongated photovoltaic modules 120 are distributed every 30 degrees around the central trunk. Connectors 140 are uniformly distributed around the perimeter of central trunk 130 in this embodiment; however connectors 140 can also be non-uniformly or randomly distributed around the central trunk 130. Although a cross-section parallel to the base of central trunk 130 of this embodiment describes a multi-sided polygon, other shapes are envisioned for central trunk 130 including, but not limited to, circles, semi-circles, ovals, oblongs, ellipses, curvilinear polygons, spirals, and irregular shapes. The basal end of each elongated photovoltaic module 120 is attached to a socket connector 140 while the distal end of each elongated photovoltaic module projects radially outward from the central trunk 130. When multiple three-dimensional elongated photovoltaic cell assemblies 200 are combined, as in the example of three-dimensional elongated photovoltaic cell assembly 100 of FIG. 1, the central trunks 130 of the assemblies 200 can be rotated such that the distal ends of adjacent elongated photovoltaic modules 120 project in different spatial directions. A similar effect of distributing elongated photovoltaic modules 120 can be achieved with a spiraled central trunk.

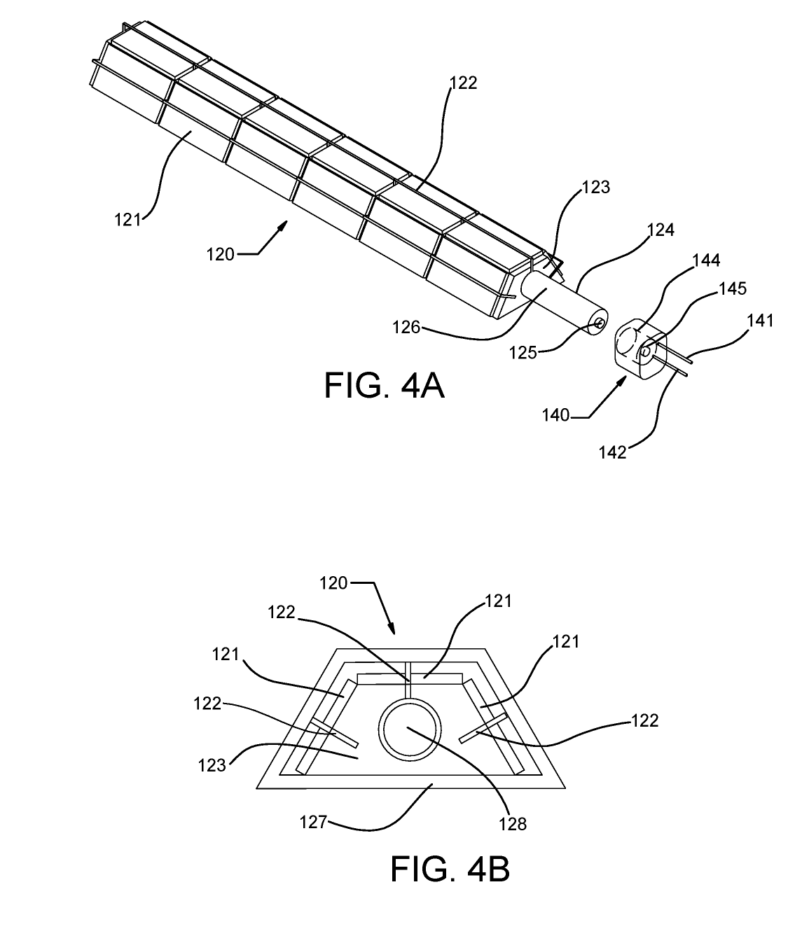

FIG. 4A illustrates a detailed perspective view of an elongated photovoltaic module 120 from three-dimensional elongated photovoltaic assembly 200 of FIG. 3. Elongated photovoltaic module 120 comprises an elongated body 123, and in the present embodiment comprises an elongated trapezoidal prism having four lateral sides. Flat rectangular photovoltaic cells 121 are mounted on the upper three lateral sides of the elongated body and are electrically connected to a module electric circuit 122. Elongated photovoltaic module 120 is further provided with a module base 126 for attachment to a socket connector 140; socket connector 140 as shown in FIG. 3 is attached to the central trunk 130. Module base terminal contacts 124 and 125 on module base 126 represent the terminals of the module electric circuit 122. Module base terminal contacts 124 and 125 can connect to the connector terminal contacts 144 and 145 on the socket connector 140. Finally, connector terminal contacts 144 and 145 can be electrically connected to the assembly central electric circuit via terminals 141 and 142. Photovoltaic cells 121 can be connected in series and/or parallel to achieve a specified voltage and current from an individual elongated photovoltaic module 120. Elongated photovoltaic modules 120 can in turn be connected in series and/or parallel to the assembly central electric circuit in order to achieve the specified voltage and current output from the entire assembly. Elongated photovoltaic modules 120 can be of varying length, for instance, the length of the modules can be longer near the bottom of a three-dimensional elongated photovoltaic cell assembly and gradually decrease towards the top of the assembly resulting in a cone-shaped assembly. Additionally, elongated photovoltaic modules 120 can be tapered, for example, the width of the modules can be wider at the basal ends than at the distal ends. Although the elongated body of the present embodiment has four lateral sides, a similar result can be achieved with a hollow elongated body comprising only the upper three sides.

A cross-section detailed view of the distal end of elongated photovoltaic module 120 of FIG. 4A is illustrated in FIG. 4B showing the placement of photovoltaic cells 121 on the top three lateral sides of the elongated body 123. A transparent weather-proof protective material 127 covers the photovoltaic cells 121 with a material being selected for optimized absorption of sunlight energy. An LED 128 is located on the distal end of elongated photovoltaic module 120; LED 128 can be electrically connected to the module electric circuit 122 and can be used to indicate the functional status of the elongated photovoltaic module 120. By-pass diodes can also be included as part of the module electric circuit 122.

Connectors 140 in the present embodiment depicted in FIG. 3 and FIG. 4A can function as a means of reversibly attaching the elongated photovoltaic modules 120 to the central trunk 130. Any male/female type connector can be utilized for connector 140 including, but not limited to, threaded, bayonet, and multi-pin connectors. The female component (socket) of a connector can be part of the central trunk and the male component (base) of a connector can be part of an elongated module, or vise versa. Other means of attaching the elongated photovoltaic modules 120 to the central trunk 130 are envisioned, including means where the modules are permanently attached and means where the module projection or attachment angle is fixed or adjustable. In the present embodiment elongated photovoltaic modules 120 are oriented orthogonally to the longitudinal axis of central trunk 130; however elongated photovoltaic modules 120 can also be attached in reclined or declined orientations.

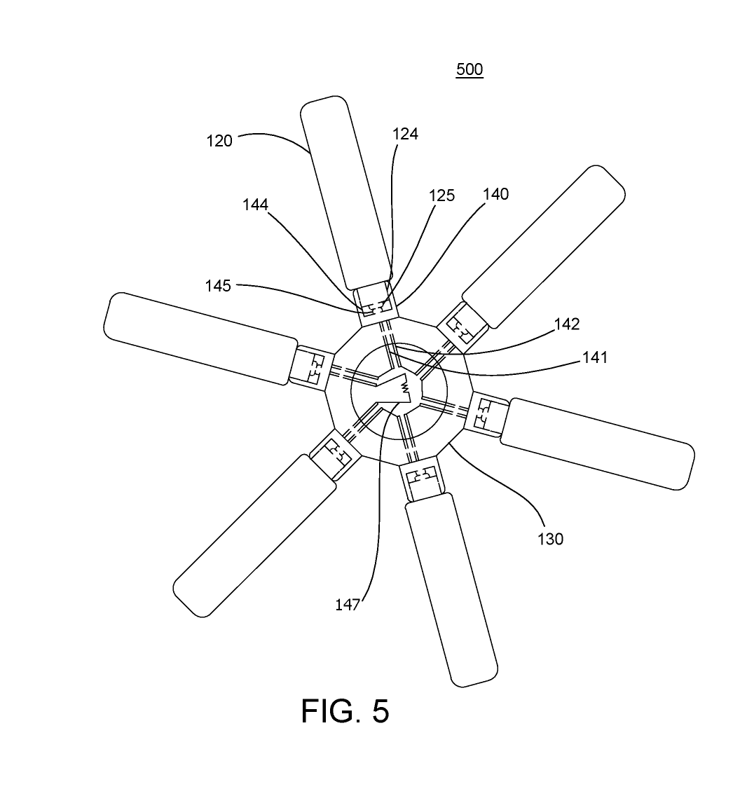

FIG. 5 shows a top view of three-dimensional elongated photovoltaic cell assembly 500 according to another embodiment of the present invention. Elongated photovoltaic modules 120 are shown to be electrically connected to each other in series and to the central electric circuit 147 via terminals 141 and 142 within the central trunk 130. Alternatively, the elongated photovoltaic modules 120 can be connected to each other in parallel or a combination of series and parallel. Module base terminal contacts 124 and 125 can be connected to the connector terminal contacts 144 and 145 on the connector 140. The central circuit 147 can be connected to additional elongated photovoltaic modules 120 to provide the desired power. For the construction of photovoltaic energy systems, the central electric circuit 147 can also include other components and capabilities such as, but not limited to, bypass and blocking diodes, chargers, inverters, maximum power point tracking, and batteries.

The intensity of solar radiation received by a photovoltaic cell is dependent on the angle of incidence or angle between the photovoltaic cell's surface normal and the sun's rays. In the present invention the three-dimensional configuration of the elongated photovoltaic modules, in conjunction with the photovoltaic cells being provided on multiple sides of the elongated photovoltaic modules, result in the photovoltaic cells facing the sun at a plurality of angles and thus having a plurality of angles of incidence at any given time of day. This is in contrast to flat two-dimensional photovoltaic assemblies of the prior art where the photovoltaic cells have essentially one solar angle of incidence at any given time. Using computer-generated models of three-dimensional elongated photovoltaic cell assembly 100 of FIG. 1, average assembly solar angles of incidence were determined for the photovoltaic cells of the plurality of elongated photovoltaic modules for solar angles ranging from 0 to 180 degrees. The intensity of solar radiation received by a photovoltaic cell is at a maximum (100%) at an angle of incidence of 0 degrees and decreases by the cosine of the angle of incidence to a minimum (0%) at an angle of incidence of 90 degrees. Solar radiation intensities received by the photovoltaic cells of three-dimensional elongated photovoltaic cell assembly 100, as percentage of the total available solar radiation, were calculated using the following equation:

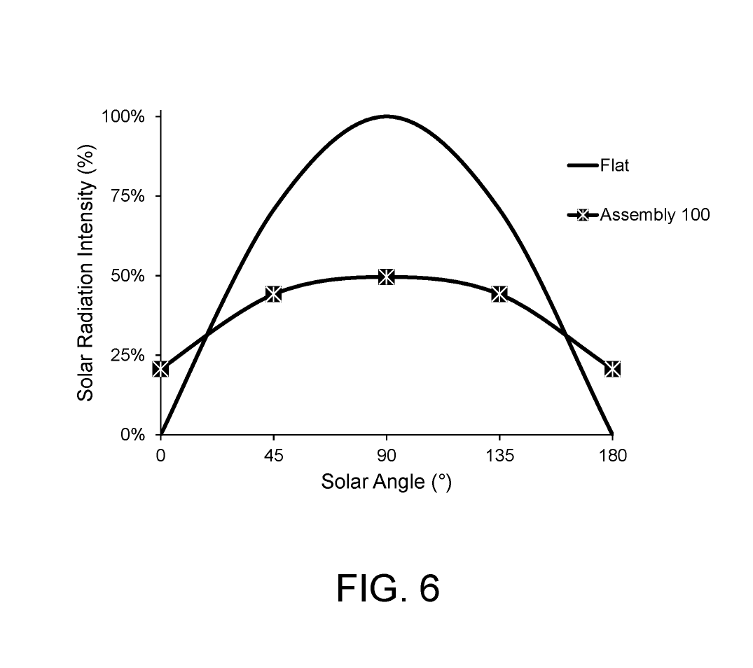

Solar Radiation Intensity (SRI)=COS(A)×100%,

where A is the average assembly solar angle of incidence for a given solar angle. FIG. 6 shows SRI values as a function of solar angle for three-dimensional elongated photovoltaic cell assembly 100 and a flat assembly. FIG. 6 illustrates how SRI values for three-dimensional elongated photovoltaic cell assembly 100 according to the present invention were more consistent than for a flat photovoltaic assembly; assembly 100 had a range of SRI values from about 20% to 50% while the flat assembly had a range from 0% to 100%. More consistent SRI values for three-dimensional elongated photovoltaic cell assemblies of the present invention can result in more uniform electric output than is possible from flat assemblies of the prior art.

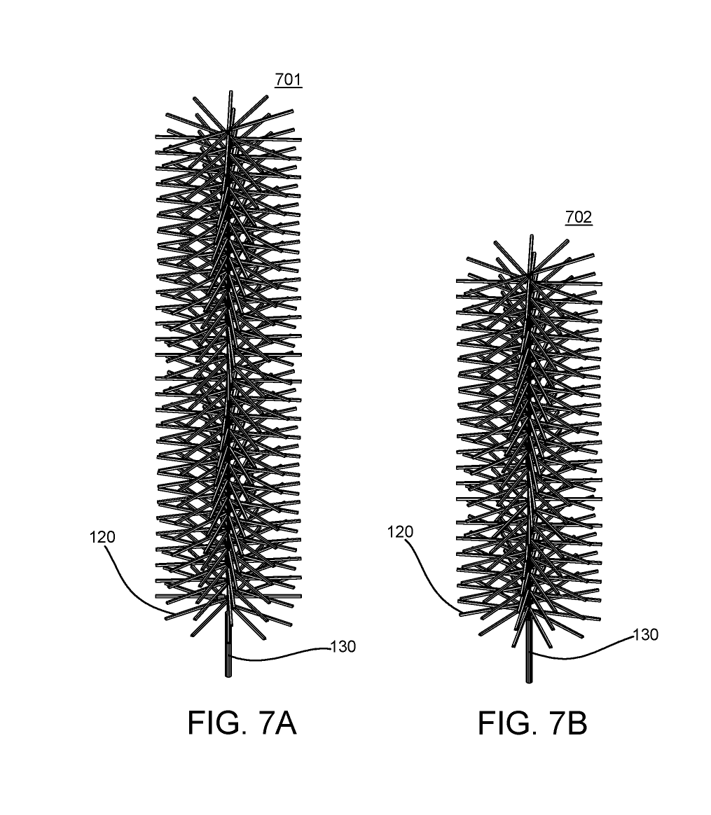

FIGS. 7A and 7B show perspective views of vertical cylindrically shaped three-dimensional elongated photovoltaic cell assemblies 701 and 702, respectively, according to another embodiment of the present invention. Three-dimensional photovoltaic assemblies 701 and 702 comprise trapezoidal prism elongated photovoltaic modules 120 similar in shape to those shown in FIG. 4A attached to central trunk 130. The specifications for assemblies 701 and 702 are given in Table I; the differences between the two assemblies can be attributed to the total number of elongated photovoltaic modules 120. Assembly 701 was provided with 336 elongated photovoltaic modules 120 and a photovoltaic surface area of 23.4 m², while assembly 702 was provided with 240 elongated photovoltaic modules 120 and a photovoltaic surface area of 16.7 m². The increased number of elongated photovoltaic modules 120 for assembly 701 was achieved by increasing the length of the central trunk 130 and thus increasing the assembly photovoltaic height from 5.5 meters for assembly 702 to 7.7 meters for assembly 701. Photovoltaic ratios were calculated by dividing the photovoltaic surface area of each assembly by an area of 2.9 m², which was the footprint of both assemblies 701 and 702.

TABLE I

| Specification | Assembly 701 | Assembly 702 |
|---|---|---|
| Assembly Height (m) | 7.7 | 5.5 |
| Number of Modules | 336 | 240 |
| Total Photovoltaic Area (m²) | 23.4 | 16.7 |
| Footprint - Area (m²) | 2.9 | 2.9 |
| Photovoltaic Ratio (3D/Flat) | 8.1 | 5.8 |

The solar irradiance profiles of assemblies 701 and 702 were obtained by first determining average assembly solar angles of incidence for solar time from 7.5 hour to 16.5 hour for an assembly location of 30 degrees north latitude on the equinox. Assembly solar radiation intensity (SRI) values were then calculated using computer-generated models as previously described for the average assembly solar angles of incidence. Additionally, since as the sun moves across the sky throughout the day there is a shading effect of the elongated photovoltaic modules due to the three-dimensional arrangement of the modules, the degree of module shading or conversely the percentage of photovoltaic area non-shaded was also determined for the assemblies for solar time from 7.5 hour to 16.5 hour. For vertical three-dimensional elongated photovoltaic cell assemblies such as assemblies 701 and 702, the amount of module shading is greatest at solar noon (12 hour) when the sun is at its highest point in the sky. Assembly Solar Irradiance (or the amount of solar radiation in KW that can be captured by an assembly) was then calculated by using the following equation:

Assembly Solar Irradiance=IG×SRI×NS×PVA,

where IG was the global solar intensity (KW/m²), SRI was the solar radiation intensity (%), NS was the degree of photovoltaic area non-shaded (%), and PVA was the total photovoltaic area (m²) of the assembly. Assembly Solar Irradiance can provide a direct indicator of the power output that could be achieved by the assemblies.

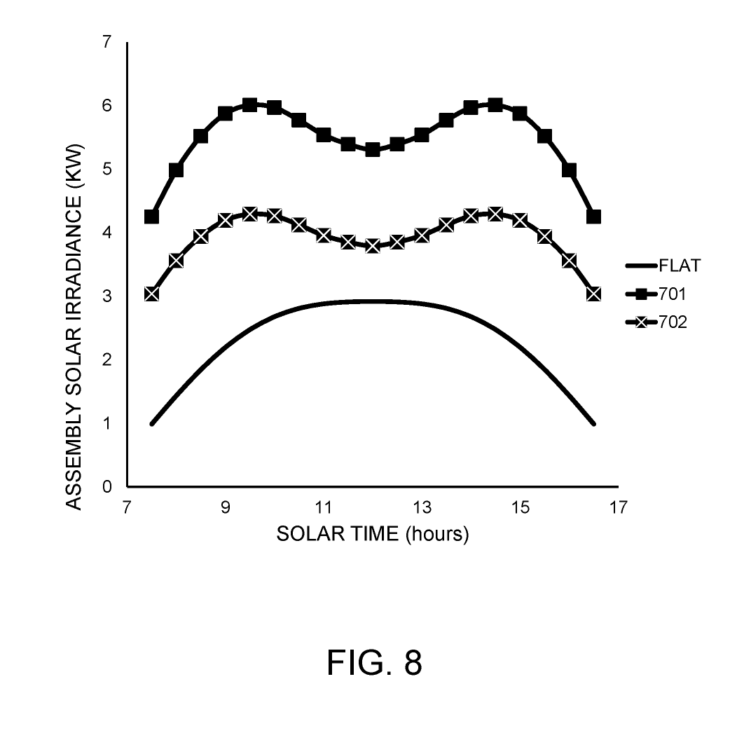

Plots of the Assembly Solar Irradiance (KW) between solar time 7.5 hour and 16.5 hour for three-dimensional elongated photovoltaic cell assemblies 701 and 702 and for a flat assembly with the same footprint are shown in FIG. 8, and the data represented in FIG. 8 is summarized in Table II. As expected, both three-dimensional elongated photovoltaic cell assemblies 701 and 702 had greater Assembly Solar Irradiance values than a flat photovoltaic assembly with the same footprint (2.9 m²) since both assemblies 701 and 702 had greater total photovoltaic areas than the flat assembly. Assembly 701 with a photovoltaic area of 23.4 m² had a Daily Assembly Solar Irradiance of 56.7 KWh/Day and assembly 702 with a photovoltaic area of 16.7 m² had a Daily Assembly Solar Irradiance of 40.5 KWh/Day, while the flat assembly with a photovoltaic area of 2.9 m² had a Daily Assembly Solar Irradiance of 22.4 KWh/Day. Furthermore, it was found that three-dimensional elongated photovoltaic cell assemblies 701 and 702 produced more consistent Assembly Solar Irradiance profiles than the flat assembly of the prior art. Both assemblies 701 and 702 exhibited similar intraday irradiance variability with ranges from high to low of about 33% compared to the flat assembly with a range of about 83%. The greater Daily Assembly Solar Irradiance and more consistent profiles for three-dimensional elongated photovoltaic cell assemblies 701 and 702, however, came with the disadvantage of requiring greater photovoltaic area per KW of irradiance.

TABLE II

| Assembly Solar Irradiance | Flat | 701 | 702 |
|---|---|---|---|
| AVG (KW) | 2.3 | 5.5 | 3.9 |
| Range - High-Low (KW) | 1.9 | 1.8 | 1.3 |
| Range - High-Low (%) | 83 | 33 | 33 |
| Daily Irradiance (KWh/Day) | 22.4 | 56.7 | 40.5 |
| Daily Irradiance Ratio (3D/Flat) | 1 | 2.5 | 1.8 |
| Photovoltaic Area (m²)/KW of | 0.13 | 0.41 | 0.41 |
| Irradiance | | | |

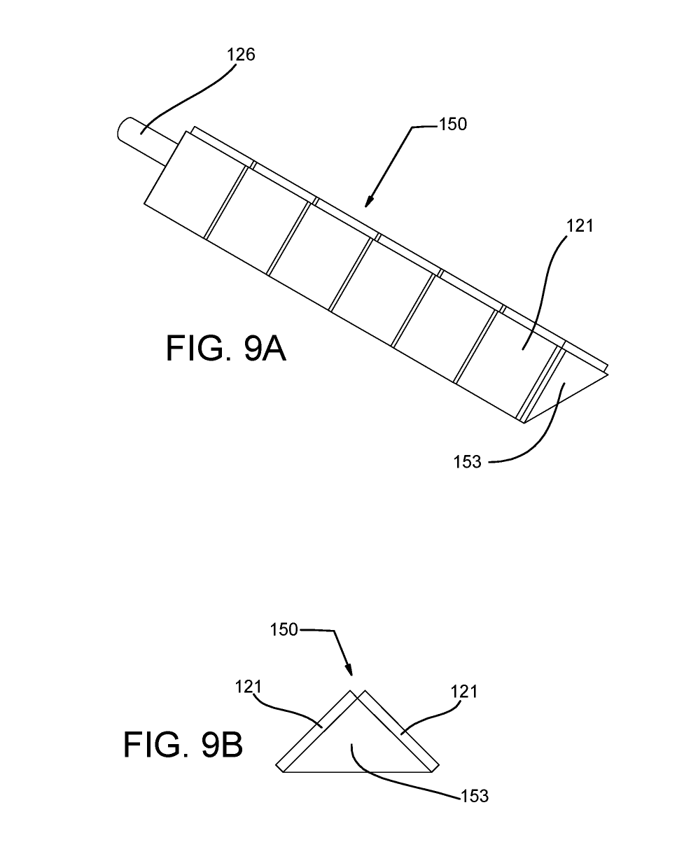

Various embodiments of elongated photovoltaic modules that can be utilized with the present invention are illustrated in FIGS. 9A, 9B, 10A, 10B, 11A, 11B, 12A, and 12B. FIGS. 9A and 9B show perspective and cross-sectional views, respectively, of an elongated photovoltaic module 150 with an elongated body comprising a multi-sided prism having a triangular cross-section. Photovoltaic cells 121 are provided only on the two top lateral sides of the elongated right triangle body 153, with a resulting angle between the two photovoltaic sides of 90 degrees. Other triangular shapes with different angles between the two top photovoltaic sides are envisioned for the elongated body, as well as hollow elongated triangular bodies comprising only the upper two lateral sides. Additionally, photovoltaic cells 121 can be provided on all three lateral sides of triangular modules. Elongated photovoltaic module 150 can be connected to three-dimensional elongated photovoltaic cell assemblies of the present invention via module base 126.

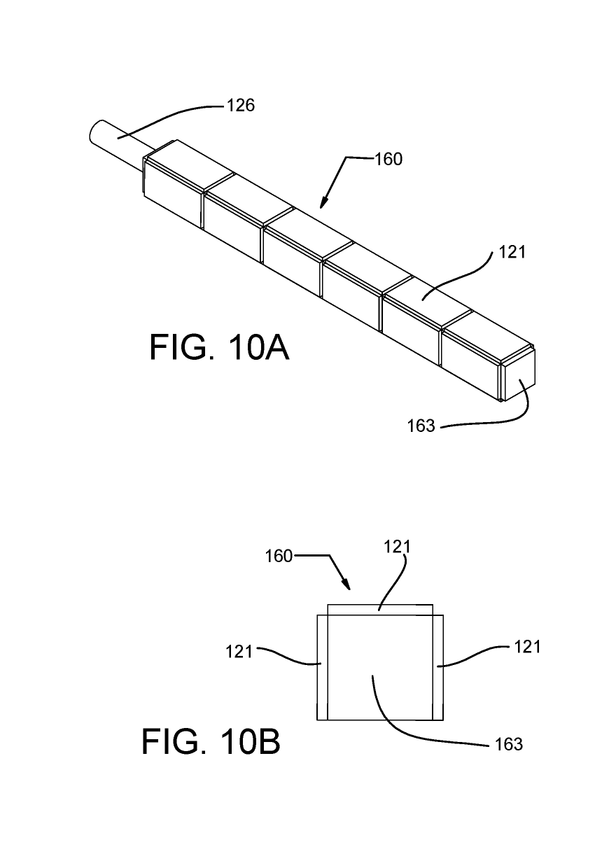

FIGS. 10A and 10B show perspective and cross-sectional views, respectively, of an elongated photovoltaic module 160 with an elongated body comprising a multi-sided prism having a rectangular (square) cross-section. Photovoltaic cells 121 are provided on the upper three lateral sides of the elongated square body 163, with a resulting angle between the photovoltaic sides of 90 degrees. Other rectangular shapes are envisioned for the elongated body, as well as hollow elongated rectangular bodies comprising only the upper three lateral sides. Additionally, photovoltaic cells 121 can be provided on all four lateral sides of elongated rectangular modules. Elongated photovoltaic module 160 can be connected to three-dimensional elongated photovoltaic cell assemblies of the present invention via module base 126.

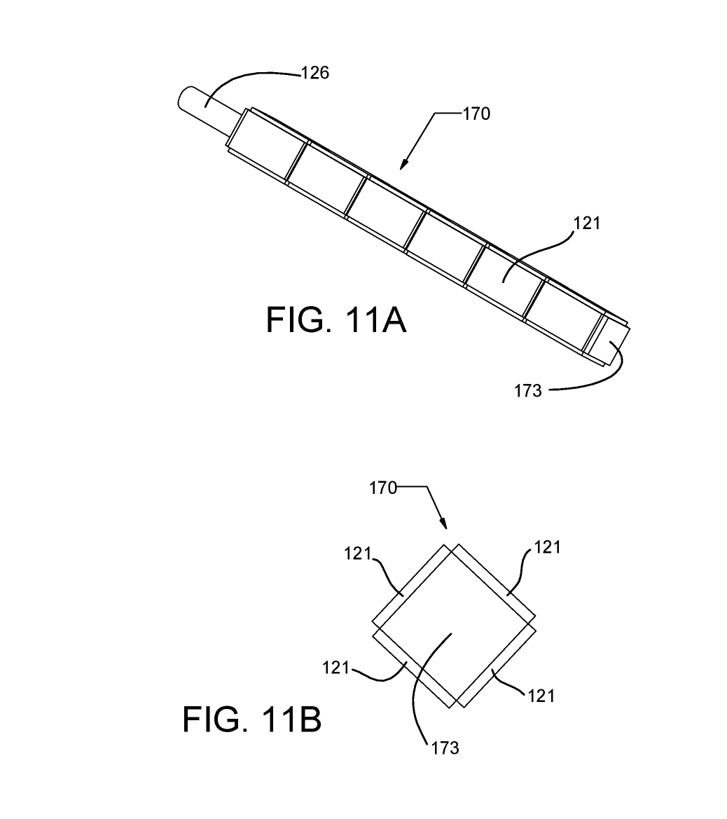

FIGS. 11A and 11B show perspective and cross-sectional views, respectively, of an elongated photovoltaic module 170 with an elongated body comprising a multi-sided prism having a diagonal square (diamond) cross-section. Photovoltaic cells 121 are provided on all lateral sides of the elongated diagonal square body 173, with a resulting angle between the photovoltaic sides of 90 degrees. Elongated photovoltaic module 170 can be connected to three-dimensional elongated photovoltaic cell assemblies of the present invention via module base 126.

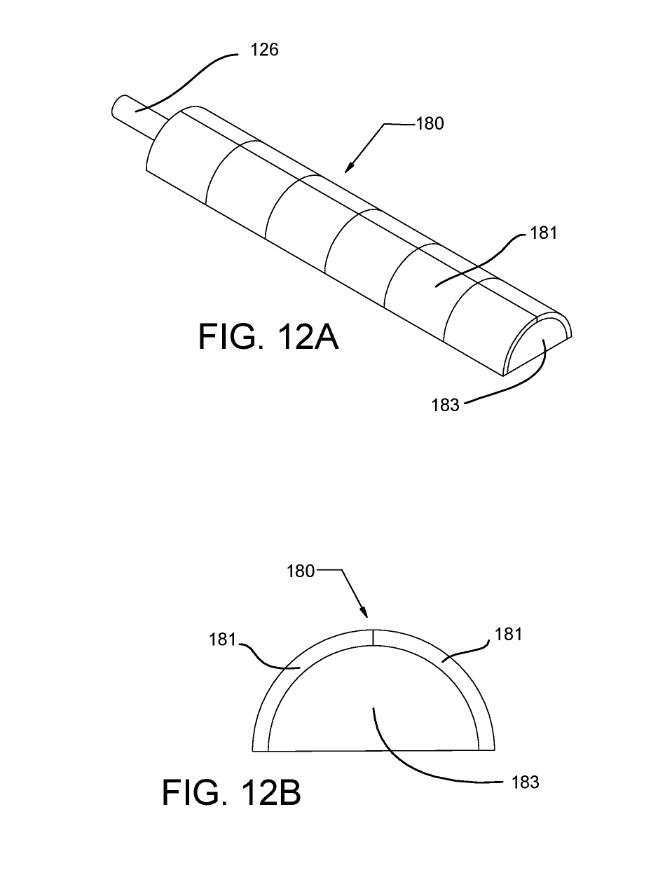

FIGS. 12A and 12B show perspective and cross-sectional views, respectively, of an elongated photovoltaic module 180 with a cylindrical elongated body having a semi-circle cross-section. Curved photovoltaic cells 181 are provided only on the top circular lateral surface of the elongated semi-circular body 183. Elongated bodies with other circular cross-section shapes such as circles, ovals, oblongs, and ellipses, as well as curvilinear shapes such as parabolas and curvilinear polygons consisting of circular arcs, are envisioned for the elongated body. Elongated photovoltaic module 180 can be connected to three-dimensional elongated photovoltaic cell assemblies of the present invention via module base 126.

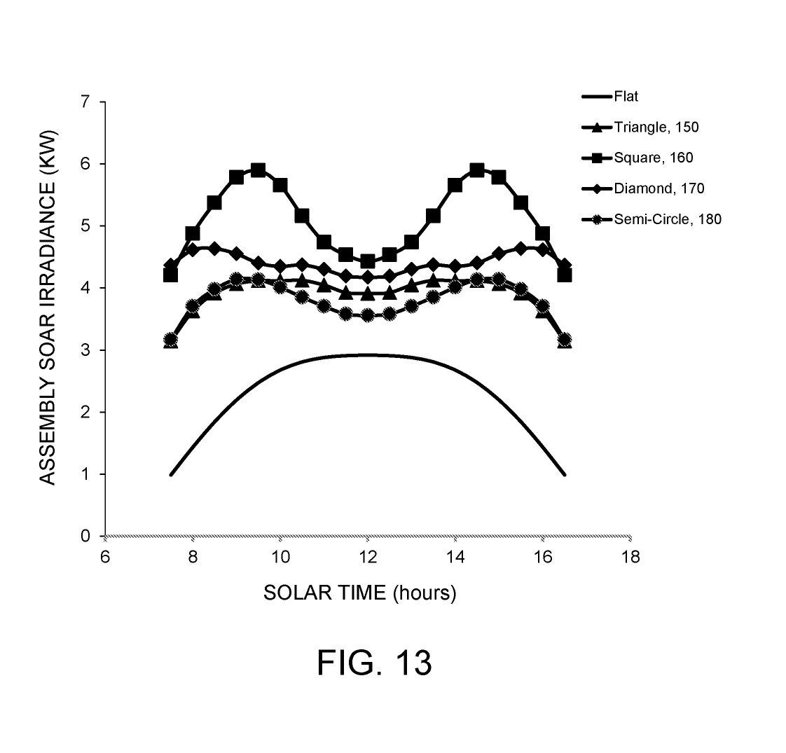

FIG. 13 shows plots of Assembly Solar Irradiance (KW) between solar time 7.5 hour and 16.5 hour for three-dimensional elongated photovoltaic cell assemblies of the present invention comprising elongated photovoltaic modules having triangle, square, diamond, and semi-circle cross-section shapes as illustrated in FIGS. 9A, 10A, 11A, and 12A, respectively and for a flat assembly. Assembly Solar Irradiance values were calculated as previously described for an assembly location of 30 degrees north latitude on the equinox. Specifications and summary of results for the photovoltaic cell assemblies represented in FIG. 13 are given in Table III. All three-dimensional elongated photovoltaic cell assemblies of the present invention, having either triangle, square, diamond, or semi-circle cross-section shaped elongated photovoltaic modules, produced more consistent Assembly Solar Irradiance profiles than a flat assembly. The diamond shaped modules 170 displayed the lowest intraday variability in Assembly Solar Irradiance with a range from high to low of about 9%, while the other elongated photovoltaic modules showed intraday variability from about 26% to 33%. Comparatively, the flat assembly had the highest intraday variability in Assembly Solar Irradiance with a range of about 83%. Due to their increased photovoltaic area all three-dimensional elongated photovoltaic cell assemblies achieved greater Daily Assembly Solar Irradiance results than a flat photovoltaic assembly with the same footprint. However, the three-dimensional elongated photovoltaic cell assemblies also required greater photovoltaic area per KW of irradiance than a flat assembly.

TABLE III

| | | 150 | 160 | 170 | 180 |
|---|---|---|---|---|---|
| Specifications & Results | Flat | Triangle | Square | Diamond | Semi-Circle |
| Number of Modules | na | 376 | 360 | 376 | 532 |
| Photovoltaic Ratio (3D/Flat) | 1 | 5.6 | 8.6 | 11.3 | 6.3 |
| Assembly Solar Irradiance AVG (KW) | 2.3 | 3.9 | 5.1 | 4.4 | 3.8 |
| Assembly Solar Irradiance - igh-Low (KW) | 1.9 | 1.0 | 1.7 | 0.4 | 1.0 |
| Assembly Solar Irradiance - High-Low (%) | 83 | 26 | 33 | 9 | 26 |
| Daily Assembly Solar Irradiance (KWh/Day) | 22.4 | 40.8 | 53.3 | 48.0 | 39.8 |
| Daily Assembly Solar Irradiance Ratio (3D/Flat) | 1 | 1.8 | 2.4 | 2.1 | 1.8 |
| Photovoltaic Area (m²)/KW of Irradiance | 0.13 | 0.40 | 0.47 | 0.68 | 0.46 |

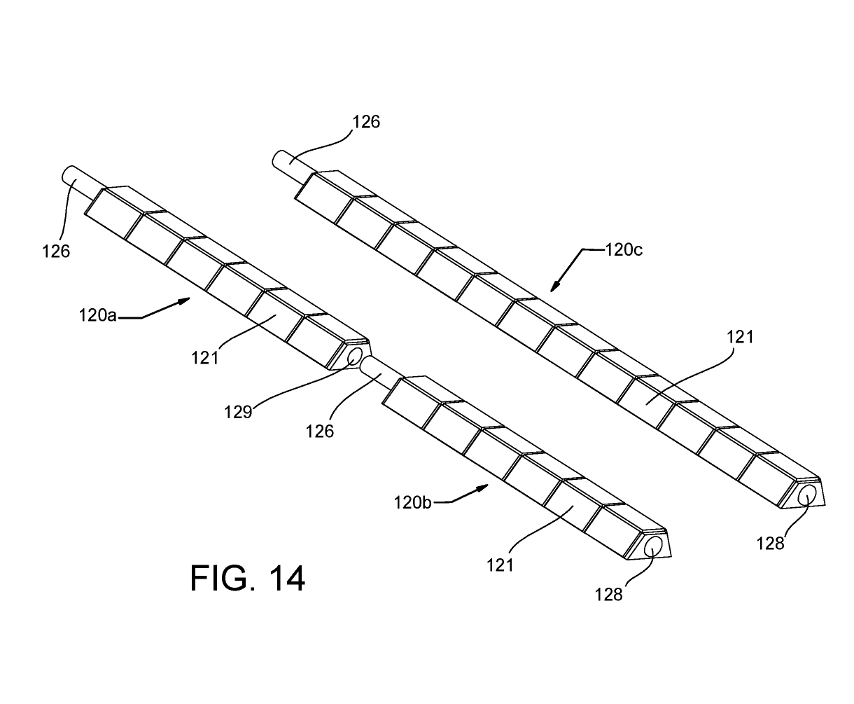

FIG. 14 illustrates an embodiment of the present invention where the basal end of a first elongated photovoltaic module can be physically and electrically connected with the distal end of a second elongated photovoltaic module as a means of increasing the overall length and photovoltaic capacity of the elongated photovoltaic modules. Elongated photovoltaic module 120a has a module base 126 at the basal end and a module receptacle 129 at the distal end. Elongated photovoltaic module 120b has a module base 126 at the basal end and an LED function-state indicator 128 at the distal end. Both modules 120a and 120b have photovoltaic cells 121 provided on the top three lateral sides. Elongated photovoltaic module 120c can be produced by inserting the module base 126 of elongated photovoltaic module 120b into module receptacle 129 of elongated photovoltaic module 120a as a means of creating both a physical and electrical connection between modules 120a and 120b. The resulting module 120c can have the combined photovoltaic capacity of modules 120a and 120b. Although this embodiment shows two elongated photovoltaic modules being combined into a single longer module, it is envisioned that greater numbers of elongated photovoltaic modules can be combined to form a specific module length and photovoltaic capacity.

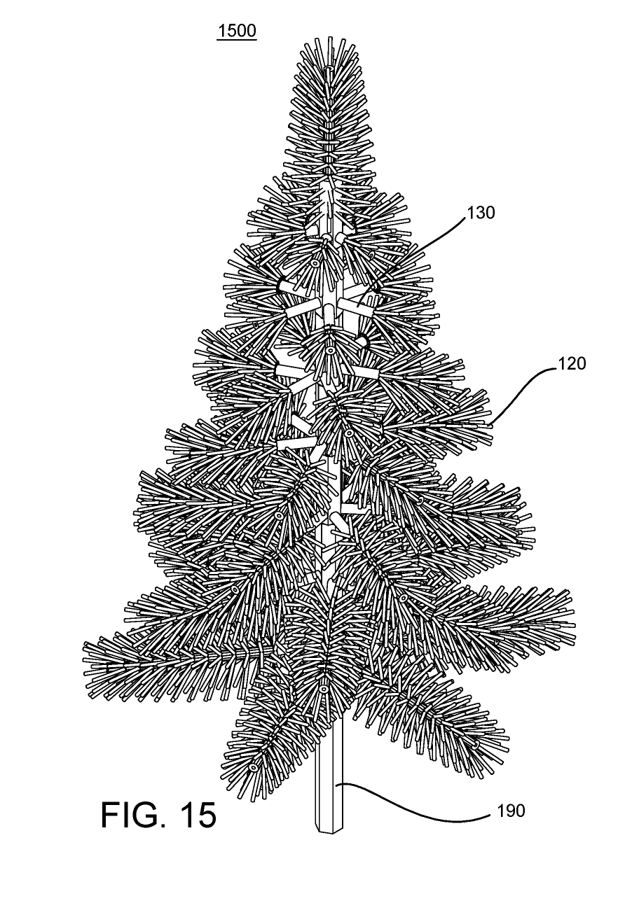

Assemblies can further comprise means of physically and electrically connecting an assembly's central trunk to the central trunk of a second assembly. An additional embodiment of the present invention illustrates how multiple three-dimensional elongated photovoltaic cell assemblies can be interconnected into larger more complex three-dimensional elongated photovoltaic cell assemblies. FIG. 15 illustrates a perspective view of a three-dimensional elongated photovoltaic cell assembly 1500 having a pine tree shape comprised of a plurality of interconnected three-dimensional elongated photovoltaic cell assemblies according to the present invention. A plurality of elongated photovoltaic modules 120 are connected to a plurality of central trunks 130 and the plurality of central trunks 130 are connected to a main central trunk 190. This embodiment can allow for larger total power production from a single three-dimensional elongated photovoltaic cell assembly. The tree shape of this embodiment can also provide more versatility for integrating photovoltaic systems into architectural projects.

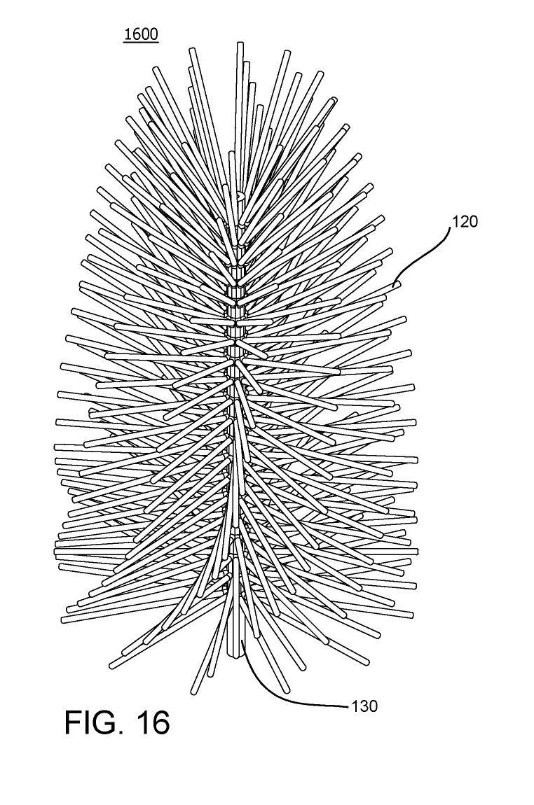

FIG. 16 illustrates a perspective view of a three-dimensional elongated photovoltaic cell assembly 1600 having elongated photovoltaic modules 120 configured at various attachment angles relative to the longitudinal axis of the central trunk 130 according to another embodiment of the present invention. Varying the attachment angle of the elongated photovoltaic modules can result in three-dimensional elongated photovoltaic cell assemblies with varying assembly shapes and irradiance profiles.

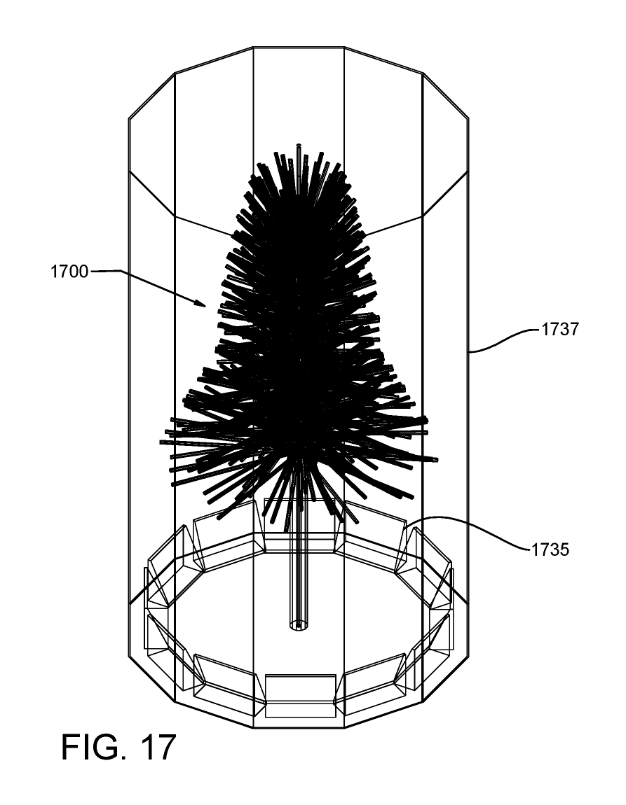

FIG. 17 illustrates a perspective view of a three-dimensional elongated photovoltaic cell assembly 1700 according to another embodiment of the present invention positioned within a protective enclosure 1737 and also provided with adjacent reflectors 1735. Protective enclosure 1737 is comprised of a clear transparent material selected to allow solar radiation to reach assembly 1700 from all angles; the inner surface of enclosure 1737 can be coated with a reflective coating. Protective enclosure 1737 can serve to protect assembly 1700 from the elements and thus help keep the assembly's photovoltaic cells clean. Reflectors 1735 comprise reflective surfaces angled to reflect solar radiation onto assembly 1700 as a means of increasing the total solar radiation reaching the assembly. Reflectors 1735 are shown positioned within enclosure 1737 in this embodiment, however, reflectors 1735 can also be positioned outside of enclosure 1737.

It is to be understood that while the invention has been described in conjunction with specific embodiments thereof, the description and examples are intended to illustrate and not limit the scope of the invention. The data presented are not intended to provide absolute performance values for the assemblies of the present invention and are only intended for comparative purposes. Other embodiments, modifications, and advantages within the scope of the invention will be apparent to those skilled in the art.

What is claimed:

1. A three-dimensional elongated photovoltaic cell assembly for generating electricity from the radiant energy of the sun comprising:
(A) a central trunk, said central trunk comprising:
a trunk body having a first trunk end, a second trunk end, and a trunk lateral surface; and
a central electric circuit with means of conducting electricity between said first trunk end and said second trunk end;
(B) a plurality of elongated photovoltaic modules, each elongated photovoltaic module of said plurality of elongated photovoltaic modules comprising:
an elongated body comprising a module basal end and a module distal end, said elongated body further comprising a multi-sided prism having a polygonal cross-section parallel to the said module basal end, wherein the lateral sides of the elongated body define non-parallel elongated panels;
a module electric circuit with means of conducting electricity between said module basal end and said module distal end; and
photovoltaic cells with means of being electrically connected to the said module electric circuit mounted along the length of at least two of the said lateral sides or elongated panels of the said elongated body;
(C) means of physically attaching the module basal end of the said plurality of elongated photovoltaic modules to the lateral surface of the said central trunk; and
(D) means of electrically connecting the module electric circuit of the said plurality of elongated photovoltaic modules to the said central electric circuit;
wherein
the module distal ends of the plurality of elongated photovoltaic modules project radially outward from the central trunk in a plurality of spatial directions; and
the photovoltaic cells on the plurality of elongated photovoltaic modules are exposed to the radiant energy of the sun at a plurality of angles of incidence at any given time of day.

2. The three-dimensional elongated photovoltaic cell assembly of claim 1 wherein the said central trunk comprises a trunk body that is cylindrical, conical, pyramidal, spherical, or prismatic.

3. The three-dimensional elongated photovoltaic cell assembly of claim 1 wherein the said central trunk further comprises means of physically and electrically connecting said central trunk to the central trunk of a second three-dimensional elongated photovoltaic cell assembly.

4. The three-dimensional elongated photovoltaic cell assembly of claim 1 wherein the said elongated body comprises a multi-sided pyramid or pyramidal frustum having a polygonal cross-section parallel to the module basal end and the polygonal cross-section is a triangle, square, diamond, trapezoid, rectangle, pentagon, hexagon, or octagon.

5. The three-dimensional elongated photovoltaic cell assembly of claim 1 wherein the said elongated body is cylindrical or conical and a cross-section parallel to the module basal end describes a circle, semi-circle, oval, ellipse, oblong, curvilinear shape such as a parabola, or an irregular curved shape, and photovoltaic cells are mounted along the lateral surface of the elongated body covering from 90 degrees to 360 degrees around the circumference of the elongated body.

6. The three-dimensional elongated photovoltaic cell assembly of claim 1 wherein a cross-section parallel to the module basal end of the said elongated body describes a curvilinear polygon consisting of circular arcs and photovoltaic cells are mounted along the lateral surface of at least two of the said circular arcs.

7. The three-dimensional elongated photovoltaic cell assembly of claim 1 wherein at least one elongated photovoltaic module of said plurality of elongated photovoltaic modules is reversibly attached to the said central trunk.

8. The three-dimensional elongated photovoltaic cell assembly of claim 1 wherein the attachment angle of the said plurality of elongated photovoltaic modules relative to the central axis of the said central trunk is reclined, orthogonal, inclined, or a combination thereof.

9. The three-dimensional elongated photovoltaic cell assembly of claim 1 wherein the attachment angle of the said plurality of elongated photovoltaic modules relative to the central axis of the said central trunk is fixed, adjustable, or a combination thereof.

10. The three-dimensional elongated photovoltaic cell assembly of claim 1 wherein at least one elongated photovoltaic module of said plurality of elongated photovoltaic modules further comprises a transparent weather-proof protective material covering the said photovoltaic cells.

11. The three-dimensional elongated photovoltaic cell assembly of claim 1 further comprising means of physically and electrically connecting the basal end of a first elongated photovoltaic module with the distal end of a second elongated photovoltaic module, thereby increasing the overall length and photovoltaic capacity of the said elongated photovoltaic modules.

12. The three-dimensional elongated photovoltaic cell assembly of claim 1 further comprising at least one visual indicator such as a light emitting diode as a means for indicating the functioning state of the elongated photovoltaic modules.

13. The three-dimensional elongated photovoltaic cell assembly of claim 1 wherein at least one elongated photovoltaic module of the said plurality of elongated photovoltaic modules comprises an elongated conductive inner electrode encased by layers of photovoltaic materials and a transparent conductive outer electrode.

14. The three-dimensional elongated photovoltaic cell assembly of claim 1 wherein at least one elongated photovoltaic module of the said plurality of elongated photovoltaic modules comprises an elongated body covered by a thin flexible photovoltaic sheet.

15. The three-dimensional elongated photovoltaic cell assembly of claim 1 wherein at least one elongated photovoltaic module of the said plurality of elongated photovoltaic modules comprises a luminescent elongated body with at least one photovoltaic cell mounted on at least one end of the luminescent elongated body.

16. The three-dimensional elongated photovoltaic cell assembly of claim 1 wherein the said plurality of elongated photovoltaic modules are all of the same type, size, shape, or length.

17. The three-dimensional elongated photovoltaic cell assembly of claim 1 wherein the said plurality of elongated photovoltaic modules are of different types, sizes, shapes, or lengths.

18. The three-dimensional elongated photovoltaic cell assembly of claim 1 further comprising a protective container sized to enclose at least part of the said three-dimensional elongated photovoltaic cell assembly wherein the said protective container is comprised of a transparent material.

19. The three-dimensional elongated photovoltaic cell assembly of claim 1 further comprising at least one reflective surface positioned in the proximity of the said three-dimensional elongated photovoltaic cell assembly as means of reflecting sunlight energy on to the said three-dimensional elongated photovoltaic cell assembly.

20. The three-dimensional elongated photovoltaic cell assembly of claim 1 further comprising by-pass diodes, blocking diodes, maximum power point tracking, chargers, inverters, and batteries.
